(19) United States
(12) Patent Application Publication
(10) Pub. No.: US 2026/0330087 A1
(43) Pub. Date: Oct. 22, 2026

(54) PLANT MODEL GENERATION DEVICE AND COMPUTER-READABLE RECORDING MEDIUM

(71) Applicant: FANUC CORPORATION, Yamanashi (JP)

(72) Inventor: Tarou OGISO, Yamanashi (JP)

(21) Appl. No.: 18/994,054

(22) PCT Filed: Sep. 7, 2022
(86) PCT No.: PCT/JP2022/033597

§ 371 Date: Jan. 14, 2025

(51) Int. Cl. G06F 30/20

(52) U.S. Cl. CPC G06F 30/20

(57) ABSTRACT

A plant model generation device according to the present disclosure is provided with: a simulation condition acquisition unit that acquires a simulation condition including at least a sample time; a characteristic parameter acquisition unit that acquires characteristic parameters indicating characteristics of a plant; a stabilization processing unit that adjusts, on the basis of the simulation condition and the characteristic parameters, a prescribed characteristic parameter such that a numerical calculation in a prescribed plant model satisfies a condition for stabilization that results in damped oscillation; and a coefficient calculation unit that calculates a coefficient of the plant model on the basis of the adjusted characteristic parameter of the prescribed plant model.

### TECHNICAL FIELD

The present invention relates to a plant model generation device and a computer-readable recording medium.

### BACKGROUND ART

For a machine to be controlled, an operation is simulated using a simulator (for example, Patent Literature 1, etc.). The simulation may be performed using data collected when the machine is actually operated. The knowledge obtained by performing the simulation is used for analyzing or designing an actual control target.

In a case where a simulation is performed to simulate a behavior of an industrial machine, the simulation is performed by modeling a servo system that causes, for example, a rotational speed of a spindle, a position of a feed axis, or the like to follow a desired value. Hereinafter, the spindle or the feed axis to be controlled in the servo system will be referred to as a plant, and a model simulating the plant will be referred to as a plant model. The behavior of the industrial machine can be modeled by, for example, an ordinary differential equation. Then, the behavior of the industrial machine can be simulated by updating a state quantity by a numerical calculation for each predetermined sample time Δt.

### CITATION LIST

### Patent Literature

Patent Literature 1: JP 2004-188541 A

### SUMMARY OF INVENTION

### Technical Problem

In the simulation in which the state quantity of the plant, in which the behavior of the industrial machine is modeled by the ordinary differential equation, is updated by the numerical calculation for each predetermined sample time Δt, the state quantity may be unstable (diverge/oscillate) depending on the system matrix A constituting the ordinary differential equation even though the operation of the actual machine is stable.

In a servo system simulator, a sample time Δt is appropriately about 0.5 to 2 times the servo control period. In a simulator in which the state quantity is unstable even though the operation of the actual machine is stable, if the sample time Δt is reduced, the destabilization can be avoided, but there is a problem that the calculation amount increases.

Therefore, in the field, there is a demand for ensuring the stability of the simulation while avoiding an increase in calculation amount.

### Solution to Problem

A plant model generation device according to the present invention solves the aforementioned problem by ensuring the stability of a plant model of a resonance system by changing a specific mechanical characteristic parameter for a simulator that simulates a behavior of a plant using an ordinary differential equation. When the adjustment of the parameter cannot achieve stabilization, the plant model of the resonance system is set to a rigid body.

One aspect of the present disclosure is a plant model generation device that generates a plant model simulating a behavior of a plant to be controlled by a numerical calculation of a predetermined formula by calculating coefficients of the numerical calculation, the plant model generation device including: a simulation condition acquisition unit configured to acquire simulation conditions including at least a sample time; a characteristic parameter acquisition unit configured to acquire characteristic parameters indicating characteristics of the plant; a stabilization processing unit configured to adjust a predetermined characteristic parameter based on the simulation conditions and the characteristic parameters such that a numerical calculation in a predetermined plant model satisfies a stabilization condition under which damped oscillation occurs; and a coefficient calculation unit configured to calculate a coefficient of the predetermined plant model based on the characteristic parameter of the predetermined plant model adjusted by the stabilization processing unit.

Another aspect of the present disclosure is a computer-readable recording medium recording a program for operating a computer as a plant model generation device that generates a plant model simulating a behavior of a plant to be controlled by a numerical calculation of a predetermined formula by calculating coefficients of the numerical calculation, in which the plant model generation device includes: a simulation condition acquisition unit configured to acquire simulation conditions including at least a sample time; a characteristic parameter acquisition unit configured to acquire characteristic parameters indicating characteristics of the plant; a stabilization processing unit configured to adjust a predetermined characteristic parameter based on the simulation conditions and the characteristic parameters such that a numerical calculation in a predetermined plant model satisfies a stabilization condition under which damped oscillation occurs; and a coefficient calculation unit configured to calculate a coefficient of the predetermined plant model based on the characteristic parameter of the predetermined plant model adjusted by the stabilization processing unit.

### Advantageous Effects of Invention

According to one aspect of the present disclosure, when constructing a simulator of a servo system, it can be expected to ensure stability of numerical calculation while avoiding an increase in calculation amount.

### BRIEF DESCRIPTION OF DRAWINGS

FIG. 1 is a schematic hardware configuration diagram of a plant model generation device according to an embodiment of the present invention.

FIG. 2 is a schematic block diagram illustrating functions of a plant model generation device according to a first embodiment of the present invention.

FIG. 3 is a diagram illustrating a configuration of a feed axis included in a plant treated as a control target.

FIG. 4 is a diagram illustrating an example of a plant model of a two-inertia resonance system.

FIG. 5 is a diagram illustrating an example of a block diagram of a two-inertia resonance system.

FIG. 6 is a diagram illustrating an example of a rigid body model.

FIG. 7 is a flowchart illustrating a flow of a process executed by a stabilization processing unit.

### DESCRIPTION OF EMBODIMENTS

Hereinafter, embodiments of the present invention will be described with reference to the drawings.

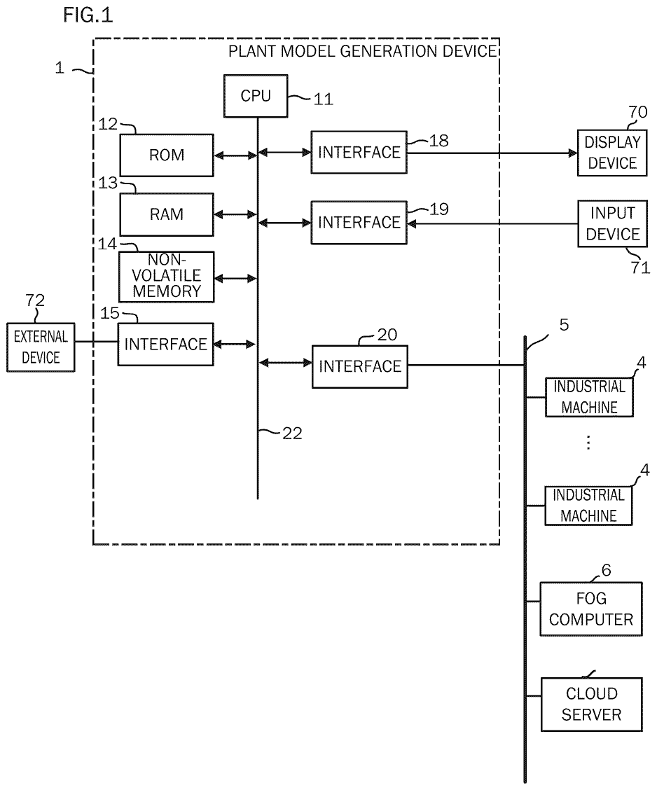

FIG. 1 is a schematic hardware configuration diagram illustrating a main part of a plant model generation device according to an embodiment of the present invention. A plant model generation device 1 of the present invention can be mounted as, for example, a controller that controls an industrial machine 4 based on a control program. Further, the plant model generation device 1 of the present invention can be mounted on a personal computer provided in a controller that controls the industrial machine 4 based on a control program, a personal computer connected to the controller via a wired/wireless network, a cell computer, a fog computer 6, or a cloud server 7. In the present embodiment, an example in which the plant model generation device 1 is mounted on a personal computer connected to the controller of the industrial machine 4 via a network will be described.

A CPU 11 included in the plant model generation device 1 of the present invention is a processor that controls the plant model generation device 1 as a whole. The CPU 11 reads a system program stored in a ROM 12 via a bus 22, and controls the entire plant model generation device 1 according to the system program. A RAM 13 temporarily stores temporary calculation data, display data, various types of data input from the outside, and the like.

A non-volatile memory 14 includes, for example, a memory, a solid state drive (SSD), or the like backed up by a battery (not illustrated) to maintain a storage state even when the plant model generation device 1 is powered off. The non-volatile memory 14 stores data and programs read from an external device 72 via an interface 15, data and programs input via an input device 71, data acquired from the industrial machine 4, and the like. The data and programs stored in the non-volatile memory 14 may be developed in the RAM 13 when executed or used. In the ROM 12, various system programs such as known analysis programs are written in advance.

The interface 15 is an interface for connecting the CPU 11 of the plant model generation device 1 and the external device 72 such as a USB device. From the external device 72, for example, programs related to the functions of the plant model generation device 1, various types of data related to the provision of services, and the like can be read. In addition, programs, various types of data, and the like edited in the plant model generation device 1 can be stored in an external storage means via the external device 72.

On a display device 70, each piece of data read on the memory, data obtained as a result of executing a program, a system program, or the like, etc. are output and displayed via an interface 18. In addition, the input device 71 including a keyboard, a pointing device, or the like passes a command, data, and the like based on an operator's operation to the CPU 11 via an interface 19.

An interface 20 is an interface for connecting the CPU 11 of the plant model generation device 1 and a network 5. The network 5 may be a wide area network (WAN) configured by a dedicated line or the like, or may be a wide area network such as the Internet. The industrial machine 4 such as a machine tool or a robot installed in a factory, the fog computer 6, the cloud server 7, and the like are connected to the network 5. These devices exchange data with the plant model generation device 1 via the network 5.

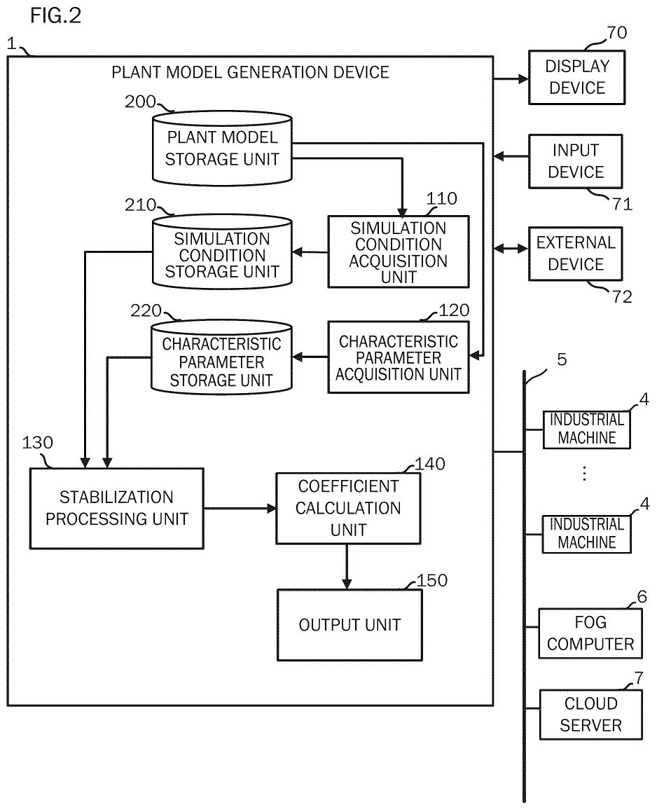

FIG. 2 is a schematic block diagram illustrating functions of a plant model generation device 1 according to a first embodiment of the present invention. The functions of the plant model generation device 1 according to the present embodiment are implemented by the CPU 11 included in the plant model generation device 1 illustrated in FIG. 1 executing a system program and controlling an operation of each unit of the plant model generation device 1.

The plant model generation device 1 of the present embodiment includes a simulation condition acquisition unit 110, a characteristic parameter acquisition unit 120, a stabilization processing unit 130, a coefficient calculation unit 140, and an output unit 150. In addition, in the RAM 13 or the non-volatile memory 14 of the plant model generation device 1, a plant model storage unit 200 which is an area in which the prototype of the plant model is stored in advance, a simulation condition storage unit 210 which is an area for storing the simulation condition acquired by the simulation condition acquisition unit 110, and a characteristic parameter storage unit 220 which is an area for storing the characteristic parameter acquired by the characteristic parameter acquisition unit 120 are prepared in advance.

The simulation condition acquisition unit 110 specifies a condition necessary for the plant model to execute a simulation based on the prototype of the plant model stored in the plant model storage unit 200. Then, the specified simulation condition is acquired and stored in the simulation condition storage unit 210. The simulation condition includes at least a sample time Δt in the simulation. For example, the simulation condition acquisition unit 110 may display a screen for prompting an input of a simulation condition on the display device 70, and acquire a simulation condition through an input from the input device 71. In addition, a simulation condition may be read and acquired from the external device 72. Furthermore, a simulation condition may be acquired from a computer such as the fog computer 6 or the cloud server 7 via the network 5.

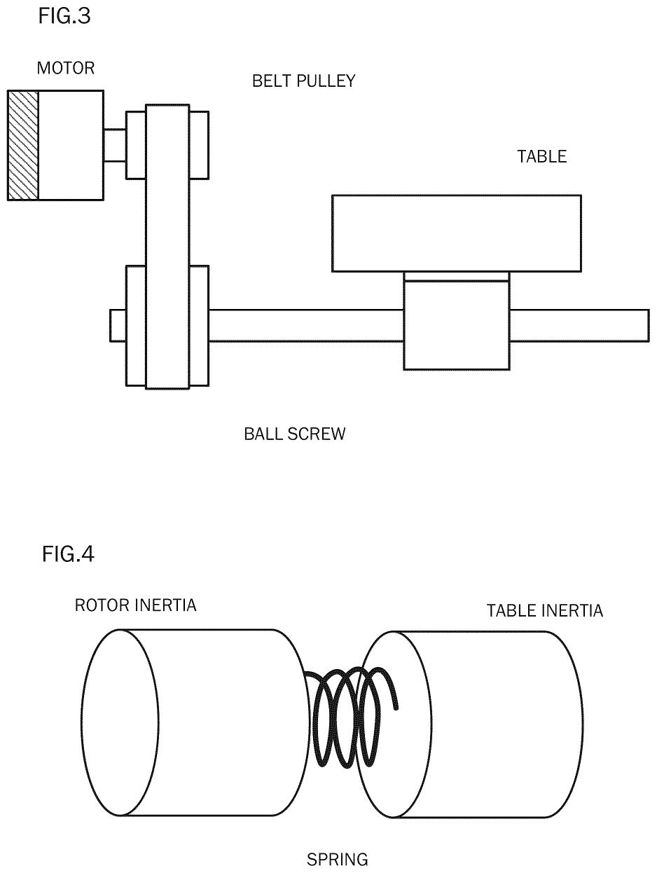

The characteristic parameter acquisition unit 120 specifies a characteristic parameter necessary for the plant model to execute a simulation based on the prototype of the plant model stored in the plant model storage unit 200. Then, the specified characteristic parameter of the plant model is acquired and stored in the characteristic parameter storage unit 220. The characteristic parameter of the plant model varies depending on the plant model. For example, a configuration of a feed axis included in a plant treated as a control target as illustrated in FIG. 3 is considered. In the example of FIG. 3, the feed axis decelerates a rotation of a motor with a belt pulley and converts the rotation into a linear motion with a ball screw to drive a table (work table). Such a control target can be modeled as a two-inertia resonance system in which the inertia of the rotor of the motor and the inertia of the rigid body such as the table are coupled by a single spring element as illustrated in FIG. 4. The single spring element refers to the belt pulley to the ball screw that are considered as one spring element.

FIG. 5 is a block diagram illustrating a model of the two-inertia resonance system. In FIG. 5, u is a torque input to the motor as an operation amount of the servo system, v_{M} is a motor velocity, vi is a table velocity, J_{M} is a rotor inertia moment, J_{L} is a table inertia moment, C_{M} is a viscous friction (damping property) of the motor, C_{T} is a damping property when the torque is transmitted between the motor and the table, K_{T} is a spring constant of the single spring element, and R is an inertia ratio between the table inertia moment J_{L} and the rotor inertia moment J_{M}. In addition, 1/(Z−1) represents an integral element. In the block diagram illustrated in FIG. 5, it is assumed that the viscous friction proportional to inertia acts on the motor and the table.

For the model illustrated in the block diagram of FIG. 5, a difference equation for calculating a motor v_{M}, of the motor, a table velocity v_{L}, and a spring element elongation x_{T} at the time (t+Δt)=(k+1) Δt in the state of the time t=kΔt can be expressed as Formula 1. Note that, in Formula 1, A is a system matrix, B is an input matrix, and 1/(Z−1) is an integral element.

$$[ Formula 1 ]$$

$$\begin{matrix}[ \begin{matrix}{v}_{{M}_{k + 1}} \\ {x}_{{T}_{k + 1}} \\ {v}_{{L}_{k + 1}}\end{matrix} ] = A [ \begin{matrix}{v}_{{M}_{k}} \\ {x}_{{T}_{k}} \\ {v}_{{L}_{k}}\end{matrix} ] + {Bu}_{k} \\ = [ \begin{matrix}1 - \frac{{C}_{M} + {C}_{T}}{{J}_{M}} Δ t & - \frac{{K}_{T}}{{J}_{M}} Δ t & \frac{{C}_{T}}{{J}_{M}} Δ t \\ Δ t & 1 & - Δ t \\ \frac{{C}_{T}}{{J}_{L}} Δ t & \frac{{K}_{T}}{{J}_{L}} Δ t & 1 - \frac{{C}_{T} + {RC}_{M}}{{J}_{L}} Δ t\end{matrix} ] [ \begin{matrix}{v}_{{M}_{k}} \\ {x}_{{T}_{k}} \\ {v}_{{L}_{k}}\end{matrix} ] + \\ [ \begin{matrix}\frac{Δ t}{{J}_{M}} \\ 0 \\ 0\end{matrix} ] {u}_{k}\end{matrix}$$

$$where {x}_{T} = \frac{Δ t}{Z - 1} ( {v}_{M} - {v}_{L} )$$

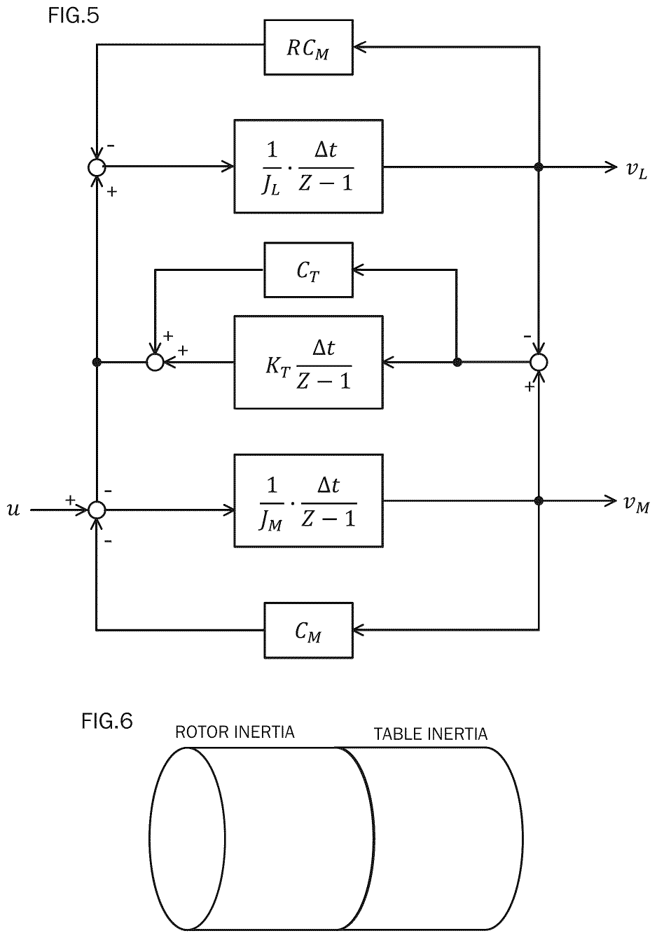

Examples of other plant models include, for example, a stiffness model. In FIG. 6, the control target is modeled as a rigid body system in which the rotor inertia of the motor and the table inertia are integrated. With this configuration, a difference equation for calculating a velocity v(=v_{M}=v_{L}) of the motor and the table at the time (t+Δt)=(k+1)Δt in the state of the time t=kΔt can be expressed as Formula 2.

$$[ Formula 2 ]$$

$${v}_{k + 1} = {v}_{k} + \frac{Δ T}{{J}_{M} ( 1 + R )} \{ {ν}_{k} - {C}_{M} ( 1 + R ) {v}_{k} \}$$

In the plant model storage unit 200, such a formula representing a characteristic of the control target is stored in advance as a plant model. The plant model storage unit 200 may store a characteristic parameter that is not included in the formula representing the plant model, and may store a relational expression indicating a relationship between the characteristic parameters. For example, the characteristic parameters of the model of the two-inertia resonance system include, in addition to those included in Formula 1, a natural frequency fₐ of the spring-table when the motor axis is fixed, a deceleration ratio r_{B} of the belt pulley, a pitch l_{S} of the ball screw, a table mass M_{L}, and the like. Such a characteristic parameter can be used to calculate another characteristic parameter. For example, the table inertia moment J_{L} can be calculated by the following Formula 3 using the deceleration ratio r_{B} of the belt pulley, the pitch l_{S} of the ball screw, and the table mass M_{L}. The spring constant K_{T} of the single spring element can be calculated by the following Formula 4 using the natural frequency fₐ of the spring-table when the motor axis is fixed and the table inertia moment J_{L}.

$$[ Formula 3 ]$$

$${J}_{L} = \frac{{M}_{L}}{{( 2 π {r}_{B} / {l}_{s} )}^{2}}$$

K_{T}=(2πfₐ)²·J_{L} [Formula 4]

The characteristic parameter acquisition unit 120 specifies a necessary characteristic parameter based on the characteristic parameters included in the formula representing the characteristic of the control target and the relational expression between the characteristic parameters. For example, those that can be calculated from other characteristic parameters such as the table inertia moment J_{L} and the spring constant K_{T} of the single spring element may be directly acquired or indirectly calculated from values of other characteristic parameters. The characteristic parameter acquisition unit 120 may acquire such a characteristic parameter of a plant model, for example, by displaying a screen for prompting an input of a characteristic parameter on the display device 70, and acquiring a characteristic parameter through an input from the input device 71. In addition, a characteristic parameter of a plant model may be read and acquired from the external device 72. Furthermore, a characteristic parameter of a plant model may be acquired from a computer such as the fog computer 6 or the cloud server 7 via the network 5.

The stabilization processing unit 130 derives a stabilization condition under which damped oscillation occurs in the plant model based on the simulation conditions stored in the simulation condition storage unit 210 and the characteristic parameters stored in the characteristic parameter acquisition unit 120. Then, when there is a stabilization condition under which damped oscillation occurs, a plant model in which a predetermined characteristic parameter is set within a range in which damped oscillation occurs is generated. On the other hand, when there is no stabilization condition under which damped oscillation occurs, a plant model in which the characteristic parameter is adjusted to be a rigid body model is generated.

As the plant model generated by the stabilization processing unit 130, one in which the operation of the control target is indicated by a predetermined formula is used. For example, a plant model of a two-inertia resonance system exemplified in Formula 1 is considered. In such a case, when the plant model is numerically calculated, a condition under which no divergence or oscillation occurs can be set as a stabilization condition. In the plant model exemplified in Formula 1, the stabilization condition can be obtained using an eigenvalue λ of the system matrix A.

In Formula 1, the eigenvalue λ of the system matrix A is represented by the following Formula 5. In Formula 5, J_{A} is a composite value of the inertia moment of the two-inertia resonance system, and C_{A} is a composite value of the damping property of the two-inertia resonance system. When the values of all the eigenvalues λ do not exceed 1, numerical calculations in the plant model are stabilized without divergence or oscillation of the state quantity.

$$[ Formula 5 ]$$

$$λ = \{ \begin{matrix}1 - \frac{{C}_{M}}{{J}_{M}} Δ t \\ 1 - \frac{Δ t}{2 {J}_{A}} ( {C}_{A} + \sqrt{{C}_{A}^{2} - 4 {J}_{A} {K}_{T}} ) \\ 1 - \frac{Δ t}{2 {J}_{A}} ( {C}_{A} - \sqrt{{C}_{A}^{2} - 4 {J}_{A} {K}_{T}} )\end{matrix} \qquad \begin{matrix}( 1 ) \\ ( 2 ) \\ ( 3 )\end{matrix}$$

$$where {J}_{A} = \frac{{J}_{M} {J}_{L}}{{J}_{M} + {J}_{L}} , {C}_{A} = \frac{R}{R + 1} {C}_{M} + {C}_{T}$$

The stabilization processing unit 130 determines a stabilization condition under which an eigenvalue λ does not exceed 1 based on the given simulation conditions and characteristic parameters. Then, simulation conditions or characteristic parameters are adjusted to stabilize numerical calculations of the plant model. At this time, characteristic parameters such as the rotor inertia moment J_{M}, the table inertia moment J_{L}, and the spring constant K_{T} of the single spring element represent characteristics that strongly control the behavior of the industrial machine 4 to be controlled. Therefore, if these characteristic parameters are adjusted, the purpose of the simulation may not be achieved. When the value of the sample time Δt decreases, the calculation amount increases. Therefore, the stabilization processing unit 130 performs an adjustment so that the eigenvalue λ does not exceed 1 by adjusting at least one of the composite value C_{A} of the damping property, the viscous friction C_{M} of the motor, and the damping property C_{T} when the torque is transmitted between the motor and the table.

The eigenvalue of Formula 5(1) is determined only by the viscous friction C_{M} of the motor regardless of the damping property C_{T} when the torque is transmitted between the motor and the table. The stabilization condition related to Formula 5(1) can be represented by the following Formula 6. Since the viscous friction C_{M} of the motor does not usually fail to satisfy the condition for stabilizing the eigenvalue of Formula 5(1), there is no need to determine the condition for stabilizing the eigenvalue.

$$[ Formula 6 ]$$

$${C}_{M} < \frac{2 {J}_{M}}{Δ t}$$

For the eigenvalues of Formulas 5(2) and 5(3), damped oscillation may occur in the plant or the plant may be overdamped depending on the composite value C_{A} of the damping property. The condition for the presence of C_{A} for damped oscillation can be represented by the following Formula 7.

ω_{γ}Δt<2 [Formula 7]

where

$${ω}_{r} = \sqrt{\frac{{K}_{T}}{{J}_{A}}}$$

In addition, the lower limit value of C_{A} satisfying the stabilization condition in a case where Formula 7 is satisfied can be represented by the following Formula 8. In Formula 8, δ is a predetermined tolerance value.

C_{A}≥K_{T}Δt+δ [Formula 8]

The upper limit value of C_{A} for damped oscillation can be represented by the following Formula 9. When C_{A} exceeds the upper limit value represented by Formula 9, the plant is overdamped. Even though the plant is overdamped, the plant is still stable. Since oscillation caused by resonance does not occur in the overdamped plant, it is preferable that C_{A} satisfies Formula 9 if a two-inertia resonance system is used as a plant model.

C_{A}≤2\sqrt{J_{A}K_{T}} [Formula 9]

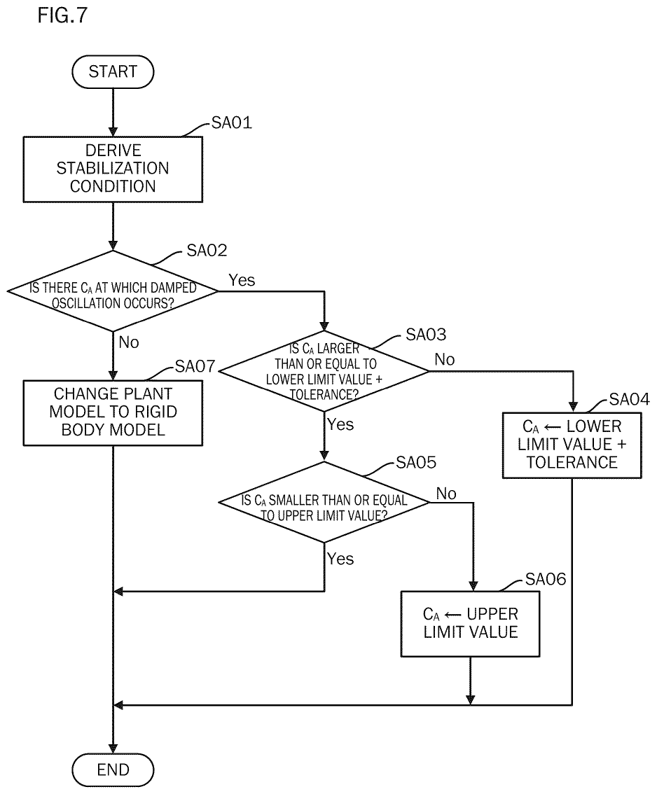

A flow of a stabilization process executed by the stabilization processing unit 130 will be described with reference to a flowchart of FIG. 7. The stabilization processing unit 130 first derives a stabilization condition for a numerical calculation of the plant model based on the simulation conditions and the characteristic parameters of the plant model (step SA01). Then, it is determined whether or not there is a composite value C_{A} of a damping property that satisfies the condition under which damped oscillation occurs, that is, whether or not the condition of Formula 7 that is a condition under which damped oscillation occurs is satisfied (step SA02). Then, when there is a composite value C_{A} of a damping property that satisfies the condition under which damped oscillation occurs (Yes in step SA02), it is next determined whether or not the composite value C_{A} of the damping property satisfies Formula 8 (step SA03). When Formula 8 is not satisfied (No in step SA03), that is, when C_{A} is smaller than a lower limit value+a tolerance value δ, at least one characteristic parameter of the composite value C_{A} of the damping property, the viscous friction C_{M} of the motor, and the damping property C_{T} when the torque is transmitted between the motor and the table is adjusted so that the composite value C_{A} of the damping property becomes K_{T}Δt+δ (step SA04).

When C_{A} is larger than or equal to the lower limit value+the tolerance value δ (Yes in step SA03), the stabilization processing unit 130 determines whether or not the composite value C_{A} of the damping property satisfies Formula 9, which represents an upper limit value of the composite value C_{A} of the damping property at which damped oscillation occurs (step SA05). When Formula 9 is not satisfied (No in step SA05), at least one characteristic parameter of the composite value C_{A} of the damping property, the viscous friction C_{M} of the motor, and the damping property C_{T} when the torque is transmitted between the motor and the table is adjusted so that the composite value C_{A} of the damping property becomes 2√(J_{A}K_{T}), which is an upper limit value (step SA06).

Then, when there is no composite value C_{A} of the damping property at which damped oscillation occurs (No in step SA02), the stabilization processing unit 130 changes the plant model to a rigid body model (step SA07). The condition for stabilizing the rigid body model is similar to that represented by Formula 6. Therefore, this stabilization condition is usually satisfied.

If the plant model is overdamped, the behavior of the industrial machine 4 can be sufficiently simulated even if the plant model is a rigid body model. Therefore, the stabilization processing unit 130 may set the plant model to a rigid body model (step SA07) in the case of No in step SA05.

The coefficient calculation unit 140 calculates each coefficient of a formula representing a plant model based on the plant model determined by the stabilization processing unit 130, the characteristic parameter of the plant model satisfying the stabilization condition, and the simulation condition. The coefficient calculation unit 140 generates a plant model by calculating each coefficient in the difference equations exemplified in, for example, Formula 1 and Formula 2 based on the characteristic parameters of the plant model determined by the stabilization processing unit 130 and the simulation conditions.

The output unit 150 outputs the plant model generated by the coefficient calculation unit 140 calculating the coefficients. For example, the output unit 150 may output a formula representing the generated plant model to the display device 70 in a displayed manner. In addition, the output unit 150 may output a formula representing the generated plant model to an external memory device, via the external device 72, in a stored manner. Furthermore, the output unit 150 may output a formula representing the generated plant model to the industrial machine 4 or to a computer such as the fog computer 6 or the cloud server 7, in a transmitted manner, via the network 5. The output plant model is used by a simulation device, a digital twin system, or the like to perform a simulation.

The plant model generation device 1 having the above-described configuration according to the present embodiment can be expected to ensure stability of numerical calculation while avoiding an increase in calculation amount when constructing a simulator of a servo system. In a case where the simulator is sold externally, if the plant model is unstable, which causes divergence or oscillation, this may be regarded as “simulator defect=software bug”. However, since the characteristic parameters are adjusted in advance by the stabilization processing unit 130 when calculating the coefficients of the plant model, the numerical calculations of the plant model are stabilized, which contributes to improving the reliability of the product.

Hereinafter, a plant model generation device 1 according to a second embodiment of the present invention will be described. The plant model generation device 1 according to the present embodiment is different from the plant model generation device 1 according to the first embodiment in the stabilization process executed by the stabilization processing unit 130.

The stabilization processing unit 130 according to the present embodiment determines whether or not a composite value C_{A} of a damping property satisfies Formula 8. Then, when Formula 8 is not satisfied, that is, when C_{A} is smaller than or equal to the lower limit value+the tolerance, a characteristic parameter is provisionally adjusted such that the composite value C_{A} of the damping property becomes K_{T}Δt+δ.

Then, the stabilization processing unit 130 determines whether or not the provisionally adjusted characteristic parameter satisfies the condition for stabilizing the overdamped plant model of the following Formula 10. When the condition is satisfied, the provisionally adjusted characteristic parameter is output as a characteristic parameter after being adjusted.

$$[ Formula 10 ]$$

$${ω}_{r} Δ t < \frac{2}{{ζ}_{r} + \sqrt{{ζ}_{r}^{2} - 1}}$$

$$where {ζ}_{r} = \frac{{C}_{A}}{2 \sqrt{{J}_{A} {K}_{T}}} , {ω}_{r} = \sqrt{\frac{{K}_{T}}{{J}_{A}}}$$

On the other hand, when the stabilization condition of Formula 10 is not satisfied, the plant model is changed to a rigid body model. The method of change to the rigid body model is similar to that according to the first embodiment.

Although the embodiments of the present invention have been described above, the present invention is not limited only to the above-described embodiments, and can be implemented in various aspects by adding appropriate modifications.

For example, in the above-described embodiments, only the plant model and the rigid body model of the two-inertia resonance system are described, but the technology of the present invention is also applicable to other plant models modeled in the form of general ordinary differential equations.

### REFERENCE SIGNS LIST

1 Plant model generation device
4 Industrial machine
5 Network
6 Fog computer
7 Cloud server
11 CPU
12 ROM
13 RAM
14 Non-volatile memory
15, 18, 19, 20 Interface
22 Bus
70 Display device
71 Input device
72 External device
110 Simulation condition acquisition unit
120 Characteristic parameter acquisition unit
130 Stabilization processing unit
140 Coefficient calculation unit
150 Output unit
200 Plant model storage unit
210 Simulation condition storage unit
220 Characteristic parameter storage unit

1. A plant model generation device that generates a plant model simulating a behavior of a plant to be controlled by a numerical calculation of a predetermined formula by calculating coefficients of the numerical calculation, the plant model generation device comprising:
a simulation condition acquisition unit configured to acquire simulation conditions including at least a sample time;
a characteristic parameter acquisition unit configured to acquire characteristic parameters indicating characteristics of the plant;
a stabilization processing unit configured to adjust a predetermined characteristic parameter based on the simulation conditions and the characteristic parameters such that a numerical calculation in a predetermined plant model satisfies a stabilization condition under which damped oscillation occurs; and
a coefficient calculation unit configured to calculate a coefficient of the predetermined plant model based on the characteristic parameter of the predetermined plant model adjusted by the stabilization processing unit.

2. The plant model generation device according to claim 1, wherein
when there is a value of the predetermined characteristic parameter that satisfies the stabilization condition under which the numerical calculation in the plant model causes damped oscillation, the stabilization processing unit adjusts the value of the predetermined characteristic parameter within a range of an upper limit value from a value obtained by adding a predetermined tolerance to a lower limit value of the stabilization condition, and
when there is no value of the predetermined characteristic parameter that satisfies the stabilization condition under which damped oscillation occurs, the stabilization processing unit changes the plant model to a rigid body model.

3. The plant model generation device according to claim 1, wherein
the stabilization processing unit provisionally adjusts a value of the predetermined characteristic parameter to be larger than or equal to a value obtained by adding a tolerance to a lower limit value of the stabilization condition under which the numerical calculation in the plant model causes damped oscillation, and
in a case where the value of the predetermined characteristic parameter is provisionally adjusted, when the condition for stabilizing the overdamped plant model is satisfied, the stabilization processing unit treats the provisionally adjusted value of the characteristic parameter as a characteristic parameter after being adjusted, and
when the condition for stabilizing the overdamped plant model is not satisfied, the stabilization processing unit changes the plant model to a rigid body model.

4. A computer-readable recording medium recording a program for operating a computer as a plant model generation device that generates a plant model simulating a behavior of a plant to be controlled by a numerical calculation of a predetermined formula by calculating coefficients of the numerical calculation, in which the plant model generation device includes:
a simulation condition acquisition unit configured to acquire simulation conditions including at least a sample time;
a characteristic parameter acquisition unit configured to acquire characteristic parameters indicating characteristics of the plant;
a stabilization processing unit configured to adjust a predetermined characteristic parameter based on the simulation conditions and the characteristic parameters such that a numerical calculation in a predetermined plant model satisfies a stabilization condition under which damped oscillation occurs; and
a coefficient calculation unit configured to calculate a coefficient of the predetermined plant model based on the characteristic parameter of the predetermined plant model adjusted by the stabilization processing unit.
